(19) United States
(12) Patent Application Publication
(10) Pub. No.: US 2014/0184274 A1
(43) Pub. Date: Jul. 3, 2014

(54) FRACTIONAL-N FREQUENCY SYNTHESIZER WITH LOW QUANTIZATION NOISE

(71) Applicant: Quadlink Technology, Ltd., Zhubei City (TW)

(72) Inventor: Ching-Lung Ti, Hsinchu County (TW)

(73) Assignee: Quadlink Technology, Ltd., Zhubei City (TW)

(21) Appl. No.: 14/025,596

(22) Filed: Sep. 12, 2013

(30) Foreign Application Priority Data
Dec. 27, 2012 (TW) 101150707

(51) Int. Cl. H03L 7/18

(52) U.S. Cl. CPC H03L 7/18
USPC 327/105

(57) ABSTRACT

A fractional-N frequency synthesizer with low quantization noise includes a phase frequency detector, a charge pump, a loop filter, a voltage controlled oscillator a divider and a Delta-Sigma modulator. The Delta-Sigma modulator computes “N” to the loop filter in the output current of the charge pump. Quantization step size in the form of current is narrowed, and that reduces the absolute energy of quantization noise reduced, resulting in wider loop bandwidth which has advantages for the fractional-N frequency synthesizer over the lock time, energy saving, and alleviates voltage controlled oscillator design constraints. Even more, frequency synthesizer achieves high frequency transmission in direct modulation transmitter.

### CROSS-REFERENCE TO RELATED APPLICATION

This application claims priority of application No. 101150707, filed on Dec. 27, 2012 in the Intellectual Property Office of The Republic of China.

### FIELD OF THE INVENTION

The invention relates to a fractional-N frequency synthesizer with low quantization noise, more particularly, to a fractional-N frequency synthesizer having advantages of less lock time, low power consumption and design constraints of the voltage controlled oscillator could be alleviated.

### BACKGROUND OF THE INVENTION

Frequency synthesizers are used in most telecommunication equipment designed to transmit or receive frequencies in certain ranges in a sub-band. A frequency synthesizer is a device that produces a waveform at a frequency determined by analog or digital circuits. The most common frequency synthesizer uses a voltage-controlled oscillator (VCO), which is controlled by a phase-locked loop (PLL) using a stable frequency reference.

For phase-locked loop synthesizer, the Integer-N Frequency Synthesis and Fractional-N Frequency Synthesis are common technologies used today, and Fractional-N Frequency Synthesis has high frequency resolution, widened loop bandwidth and high reference frequency than the Integer-N Frequency Synthesis. In addition, Fractional-N Frequency Synthesis can meet both agile lock time and fine frequency resolution. Nowadays Fractional-N Frequency Synthesis is mainly used in RF transceivers for GPRS applications that require very fast lock time of 150 μs.

By using fractional-N division, the wider loop bandwidth for a given channel spacing allows faster settling time and reduced phase noise requirements to be imposed on the voltage-controlled oscillator (VCO). The faster settling time, resulting from broader loop bandwidth of a PLL-based fractional-N frequency synthesis, has the potential to eliminate additional hardware.

In Fractional-N Frequency Synthesizer, N is a rational number rather than an integer. Fractional-N architecture allows frequency resolution to be a fractional portion of the reference frequency, Fr. Therefore Fr can be higher than the step size and overall division (by N) can be reduced. The concept of fractional-N is achieved by generating a divider that is a fractional number rather than an integer. The principle of fractionality is a result of averaging, as there is no device that can be divided by a fraction.

In the frequency spectrum, the Delta-Sigma Modulator pushes the Quantization Noise to the high frequency, that limits the frequency synthesizer for wider high frequency (<150 kHz). The low bandwidth has disadvantages for the fractional-N frequency synthesizer over the lock time, voltage controlled oscillator's noise, and energy consumption, or cannot be utilized in direct modulation transmitter.

Referring to FIG. 1, a circuit block diagram illustrates a conventional fractional-N frequency synthesizer 1, which includes a phase frequency detector (PFD) 11, a charge pump 12, a loop filter (LPF) 13, a voltage controlled oscillator (VCO) 14, an divider 15 and an Delta-Sigma Modulator 16.

The phase frequency detector 11 generates a phase frequency signal 120 in response to the difference in frequency and phase of a received reference frequency signal and a divided frequency signal from the divider 15.

The charge pump 12 generates a current in response to the phase frequency signal.

The loop filter 13 generates a voltage control signal in response to the current, and provides the voltage control signal to the voltage controlled oscillator 14.

The voltage controlled oscillator 14 receives the voltage control signal and generates an output frequency signal, which contains voltage control frequency.

The integer divider 15 generates the divided frequency signal in response to the output frequency signal.

The fractional-N frequency synthesizer further includes a Delta-Sigma modulator 16 for modulating the fractional divider.

In reality, the quantization noise is of course not independent from the signal. This dependence is the source of idle tones and pattern noise in Sigma-Delta converters. The quantization noise is introduced to the circuit loop from the output of the divider. The noise appears on the high frequency, thus the design of bandwidth of the fractional-N frequency synthesizer determines the noise size.

As illustrated in FIG. 2, the quantization noise through the circuit loop with frequency response obtains the effect of filtering at the output of divider 15. The fractional-N scheme is a scheme that can divide the oscillation frequency of a voltage controlled oscillator by a division ratio having a fractional value. The narrow bandwidth provides attenuation of the quantization noise, causing small phase noise produced by Delta-Sigma modulator 16, observed from the output end. However, narrow bandwidth design brings drawbacks on the circuit and the most apparent one is the increase of design cost.

In order to solve the problem(s), the present invention introduces a fractional-N frequency synthesizer with low quantization noise.

### SUMMARY OF THE INVENTION

The primary objective of the present invention is to provide a fractional-N frequency synthesizer with low quantization noise.

In order to accomplish the aforementioned objective, the fractional-N frequency synthesizer of the preferred embodiment of the present invention includes:

a phase frequency detector, having two inputs to receive a reference frequency with a first phase and a divided frequency with a second phase, wherein the phase frequency detector generates a phase error signal indicative of phase difference between the first phase and the second phase;

a charge pump, operably coupled to the phase frequency detector for generating a compensation current in response to the phase error signal;

a loop filter, operably coupled to the charge pump for receiving and smoothing the compensation current, and to provide a filtered control signal in response to the compensation current;

a voltage controlled oscillator, coupled to the loop filter for providing an output frequency signal with a voltage control frequency in response to the filtered control signal;

a divider, coupled to the voltage controlled oscillator for receiving and dividing the output frequency signal by a dividing ratio, and providing a frequency divided output signal responsive to the output frequency signal; and

a Delta-Sigma modulator, having a pulse input and a number input and an overflow output, the pulse input coupled to the divider to receive the frequency divided output signal, the number input receiving a value, and the overflow output coupled to the loop filter and the divider, wherein the Delta-Sigma modulator computes the value to the loop filter and the divider, and determines the ratio between the reference frequency and the voltage control frequency.

It is to be noted from the objectives of the preferred embodiment of the present invention that the invention conducts a quantization noise to the input of circuit loop. The Delta-Sigma modulator computes “N” to the loop filter in the output current of the charge pump. Quantization step size in the form of current is scale-down (narrow down), and that causes the absolute energy of quantization noise to be reduced, in wider loop bandwidth which has advantages for the fractional-N frequency synthesizer over the lock time, design constraints of voltage controlled oscillators, and energy saving, even more, frequency synthesizer achieves high frequency transmission in direct modulation transmitter.

### BRIEF DESCRIPTION OF THE DRAWINGS

FIG. 1 is a circuit block diagram of the conventional fractional-N frequency synthesizer.

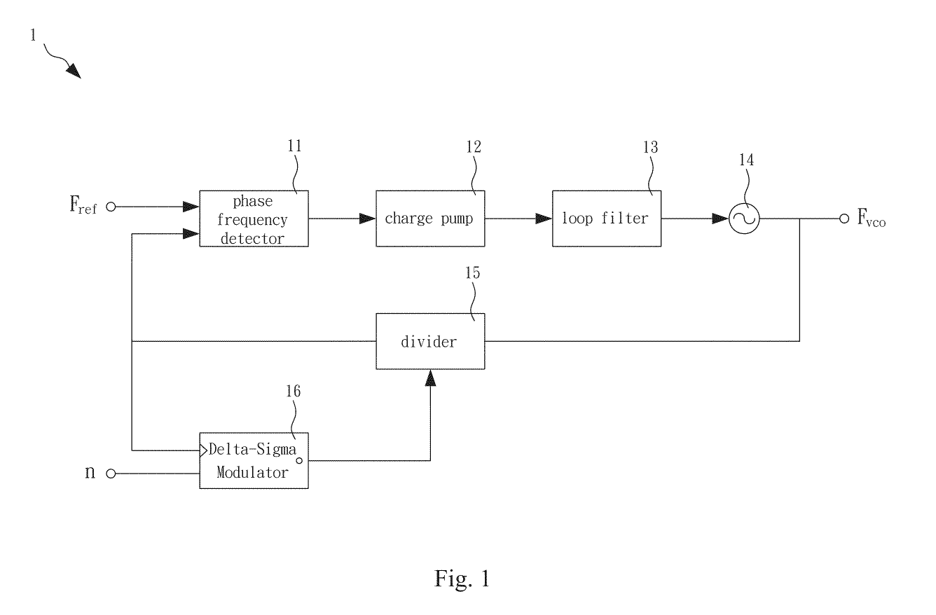

FIG. 2 is a quantization noise signal graph of the conventional fractional-N frequency synthesizer.

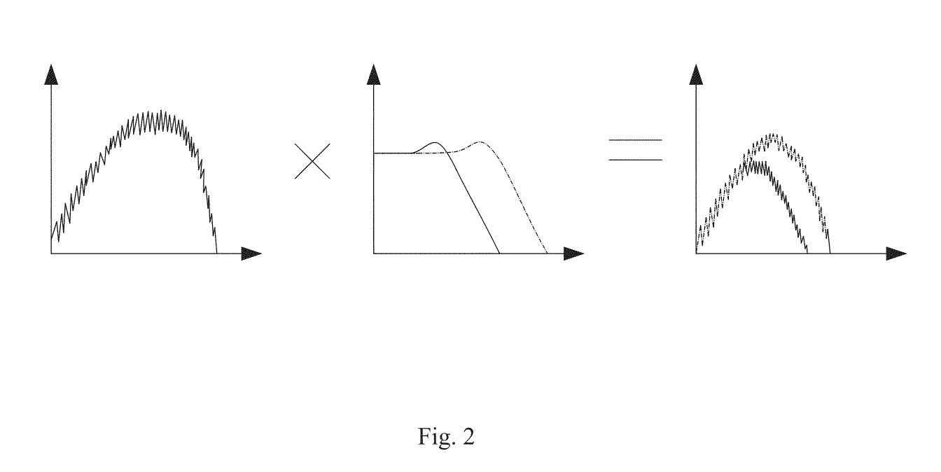

FIG. 3 is a circuit schematic diagram showing a fractional-N frequency synthesizer according to the preferred embodiment of the present invention.

FIG. 4 is still a circuit schematic diagram showing a fractional-N frequency synthesizer according to the preferred embodiment of the present invention.

FIG. 5 is a simulation graph of the modulated current in the fractional-N frequency synthesizer according to the embodiment of the present invention.

### DETAILED DESCRIPTION OF THE INVENTION

The following description is merely exemplary in nature and is in no way intended to limit the present teachings, applications, or uses. Those of skill in the art will recognize that the following description is merely illustrative of the principles of the invention, which may be applied in various ways to provide many different alternative embodiments.

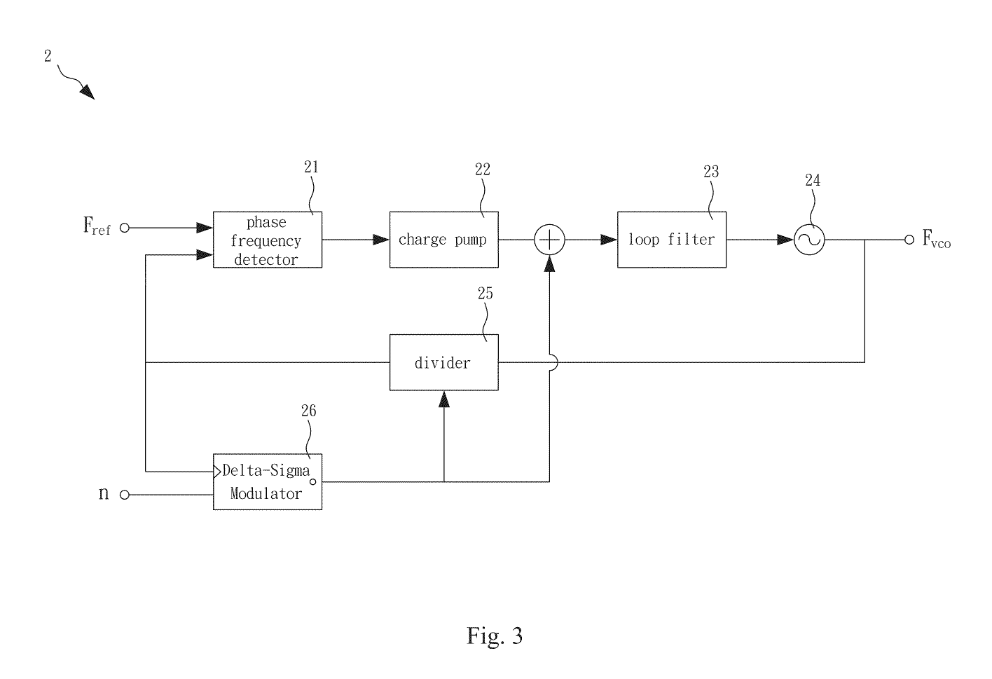

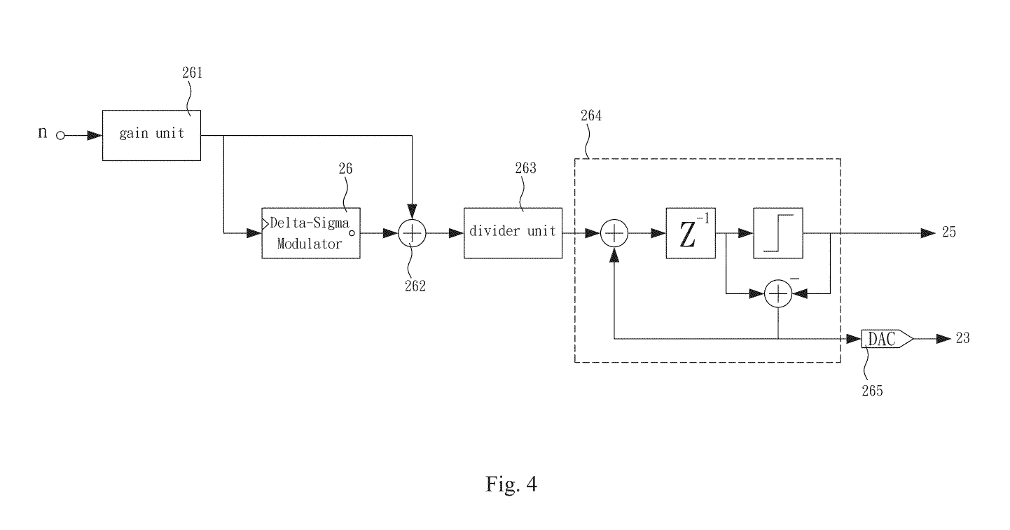

With references to FIG. 3 and FIG. 4, circuit schematic diagrams show a fractional-N frequency synthesizer according to the preferred embodiment of the present invention. There is shown the circuit schematic diagram 2 has a phase frequency detector 21, a charge pump 22, a loop filter 23, a voltage controlled oscillator 24, a divider 25 and a Delta-Sigma modulator 26.

The phase frequency detector 21 has two inputs to receive a reference frequency (Fref) and a divided frequency. The phase frequency detector 21 compares a phase of the reference frequency with a phase of the divided frequency, and outputs a phase error signal indicative of a difference therebetween.

The charge pump 22 is operably coupled to the phase frequency detector 21 to generate a compensation current in response to the phase error signal.

The loop filter 23 is operably coupled to the charge pump 22 to receive and smooth the compensation current. The loop filter 23 provides a filtered control signal in response to the compensation current.

The voltage controlled oscillator 24 is operably coupled to the loop filter, and provides an output frequency signal with a voltage control frequency (Fvco) in response to the filtered control signal.

The divider 25 is operably coupled to the voltage controlled oscillator 24 and phase frequency detector 21 for receiving and dividing the output frequency signal by a dividing ratio. The divider 25 provides a frequency divided output signal responsive to the output frequency signal.

The Delta-Sigma modulator 26 has a pulse input and a number input and provides an overflow output. The pulse input is coupled to the divider 25 to receive the frequency divided output signal. The number input receives a value, and the overflow output is coupled to the loop filter 23 and the divider 25. The Delta-Sigma modulator 26 computes the value to the loop filter 23 and the divider 25, and determines a ratio between the reference frequency and the voltage control frequency.

Referring to FIG. 4, a circuit schematic diagram shows a fractional-N frequency synthesizer according to the preferred embodiment of the present invention. The fractional-N frequency synthesizer 2 has units including a gain unit 261, an adder unit 262, a divider unit 263, an integrator unit 264, and a digital-to-analog converter 265.

The gain unit 261 receives a value N and generates a first number and a second number which is transferred to the number input of the Delta-Sigma modulator 26.

The adder unit 262 is coupled to the Delta-Sigma modulator 26 and the gain unit 261, and adds the first number and the second number to output a first modulation value.

The divider unit 263 is coupled to the adder unit 262 and receives the first modulation value. The divider unit 263 divides the first modulation value to generate a second modulation value.

The integrator unit 264 is coupled to the divider unit 263 and receives the second modulation value. The integrator unit 264 integrates the second modulation value to generate a third modulation value to the divider 25.

The digital-to-analog converter 265 is coupled to the integrator unit 264 and receives the third modulation value. The digital-to-analog converter 265 provides transformation of the third modulation value to output to the loop filter 23.

Accordingly, the gain unit 261 has a value of power of two, and the divider unit 263 also has a value of power of two.

Referring to FIG. 3, connections among the elements of the fractional-N frequency synthesizer 2 is described more fully hereinafter. The invention conducts the quantization noise to the input of circuit loop and the divider 25 instead of the divider 25 only, and the Delta-Sigma modulator 26 computes “N” to output to the loop filter 23 in current form. In FIG. 3 shown the output current is added to the current from the charge pump 22. Quantization step size in the form of current is scale-down (narrow down), that reduces the absolute energy of quantization noise proportionally, resulting in wider loop bandwidth which has advantages for the fractional-N frequency synthesizer 2 over the lock time, energy saving, and alleviates voltage controlled oscillator design constraints. Even more, the frequency synthesizer achieves high frequency transmission in direct modulation transmitter.

Referring to FIG. 4, the circuit schematic diagram of the fractional-N frequency synthesizer according to the embodiment of the present invention is shown. The gain unit 261 receives the value N whose fractional part is obtained and magnified by A_{Δ} to generate a new value, where A_{Δ} is a power of two. The integer part of the new value represents the first number, and the fractional part of the new value represents the second number which is transmitted to the input of the Delta-Sigma modulator 26.

Next, the adder unit 262 adds the first number and the second number to output a first modulation value. The divider unit 263 provides division for the first modulation value with A_{Δ} to output a second modulation value, where A_{Δ} is a power of two. Equivalently, the quantization step size is scale-down in the second modulation value, and the quantization noise is input in the form of current. In the circuit loop the divisor (frequency) is converted to phase, then it goes through the integrator unit 264 to have same frequency response in the circuit loop. The overflow from the integrator unit 264 is adding 1 to the divisor to keep the continuity of phase changes.

Accordingly, the output of the integrator unit 264 is transmitted to the divider 25, and to the loop filter 23 via a Digital Analog Converter (DAC) 265.

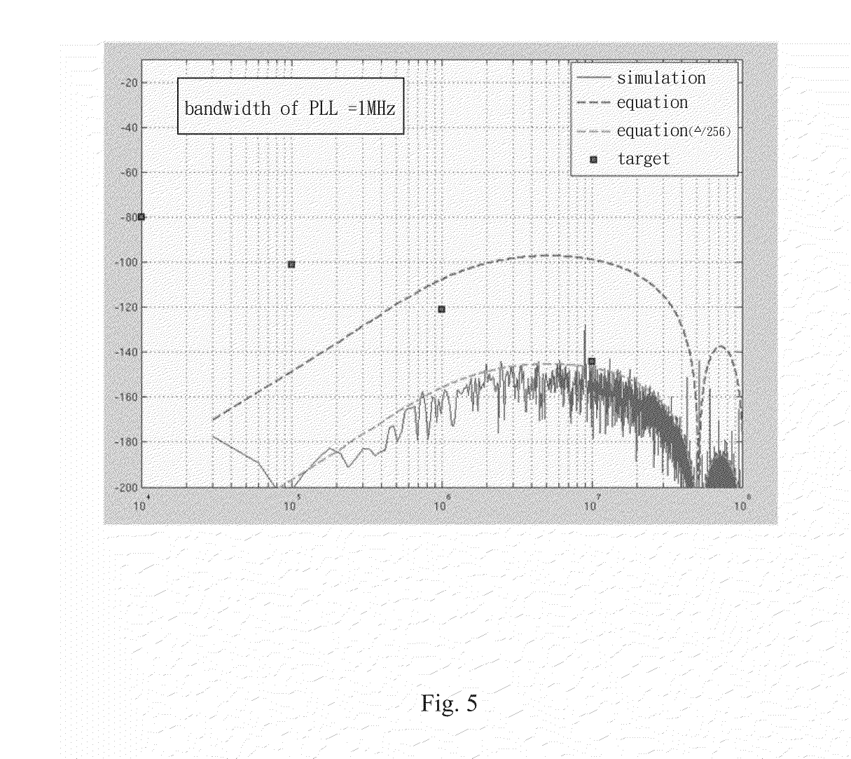

Referring to FIG. 5, a simulation of the modulated current in the fractional-N frequency synthesizer according to the embodiment of the present invention is shown. Quantization step size is 1/256 (8 bit DAC) to reduce quantization noise for 256 times, equally the phase noise is reduced by 48 dB. In the 1 MHz frequency offset, the phase noise affected by the quantization noise is below the level of −140 dBc/Hz. In comparing with traditional fractional-N frequency synthesizer in the same loop wideband of 1 MHz frequency, the prior art is unable to achieve the same level.

The disclosed circuit provides a new design in less lock time, low power consumption and alleviates the voltage controlled oscillator design constraints. The embodiments of the present invention are practiced in a variety of devices that utilize disclosed fractional-N frequency synthesizer and, in particular, frequency synthesizer achieves high frequency transmission (1 MHz) in direct modulation transmitter.

It is to be noted that although the preferred embodiment of the present invention has been described, other modifications, alterations or minor change to the structure should still be within the scope defined in the claims. As those skilled in the art will readily observe that numerous modifications and alterations of the device and method may be made while retaining the teachings of the invention.

What is claimed is:

1. A fractional-N frequency synthesizer with low quantization noise, comprising:
a phase frequency detector, having two inputs to receive a reference frequency with a first phase and a divided frequency with a second phase, wherein the phase frequency detector generates a phase error signal indicative of phase difference between the first phase and the second phase;
a charge pump, operably coupled to the phase frequency detector for generating a compensation current in response to the phase error signal;
a loop filter, operably coupled to the charge pump for receiving and smoothing the compensation current, and to provide a filtered control signal in response to the compensation current;
a voltage controlled oscillator, coupled to the loop filter for providing an output frequency signal with a voltage control frequency in response to the filtered control signal;
a divider, coupled to the voltage controlled oscillator for receiving and dividing the output frequency signal by a dividing ratio, and providing a frequency divided output signal responsive to the output frequency signal; and
a Delta-Sigma modulator, having a pulse input and a number input and an overflow output, the pulse input coupled to the divider to receive the frequency divided output signal, the number input receiving a value, and the overflow output coupled to the loop filter and the divider, wherein the Delta-Sigma modulator computes the value to the loop filter and the divider, and determines a ratio between the reference frequency and the voltage control frequency.

2. The fractional-N frequency synthesizer as claimed in claim 1 further including:
a gain unit, receiving the value and producing a first number and a second number which is transferred to the number input of the Delta-Sigma modulator;
an adder unit, coupled to the Delta-Sigma modulator and the gain unit for adding the first number and the second number to output a first modulation value;
a divider unit, coupled to the adder unit to receive the first modulation value for dividing the first modulation value to generate a second modulation value;
an integrator unit, coupled to the divider unit to receive the second modulation value for integrating the second modulation value to generate a third modulation value to the divider; and
a digital-to-analog converter, coupled to the integrator unit and to receive the third modulation value for providing transformation of the third modulation value to output to the loop filter.

3. The fractional-N frequency synthesizer as claimed in claim 2, wherein the gain unit has a value of power of two.

4. The fractional-N frequency synthesizer as claimed in claim 2, wherein the divider unit has a value of power of two.
